(19) United States
(12) Patent Application Publication
(10) Pub. No.: US 2024/0021530 A1
(43) Pub. Date: Jan. 18, 2024

(54) SEMICONDUCTOR PACKAGE INCLUDING CONNECTION LAYER

(71) Applicants: YOONYOUNG JEON, Suwon-si (KR); Minju KIM, Suwon-si (KR); MIN JI KIM, Suwon-si (KR); YOUNGMIN KIM, Suwon-si (KR); Changbo LEE, Suwon-si (KR)

(72) Inventors: YOONYOUNG JEON, Suwon-si (KR); Minju KIM, Suwon-si (KR); MIN JI KIM, Suwon-si (KR); YOUNGMIN KIM, Suwon-si (KR); Changbo LEE, Suwon-si (KR)

(21) Appl. No.: 18/178,507

(22) Filed: Mar. 5, 2023

(30) Foreign Application Priority Data
Jul. 14, 2022 (KR) 10-2022-0087089

(51) Int. Cl. H01L 23/538; H01L 21/48; H01L 21/56; H10B 80/00; H01L 23/00; H01L 23/31

(52) U.S. Cl. CPC H01L 23/5386; H01L 23/5385; H01L 21/4857; H01L 21/486; H01L 21/568; H10B 80/00; H01L 24/05; H01L 24/13; H01L 24/16; H01L 23/3128; H01L 2224/05624; H01L 2224/05571; H01L 2224/13111; H01L 2224/13139; H01L 2224/16238; H01L 24/81; H01L 2224/81444; H01L 2224/48227; H01L 2224/48091; H01L 2224/48105; H01L 24/48; H01L 2924/1431; H01L 2924/1436; H01L 2924/14511

(57) ABSTRACT

A semiconductor package includes a first semiconductor package and a second semiconductor package on the first semiconductor package. The first semiconductor package includes a lower redistribution substrate, a connection substrate on the lower redistribution substrate, the connection substrate includes a through hole, a first insulating layer and a through via penetrating the first insulating layer, a lower semiconductor chip in the through hole, a connection layer between the connection substrate and the lower redistribution substrate, the connection layer includes a first metal pattern and a solder pattern on the first metal pattern, a first molding layer on the lower semiconductor chip and the connection substrate, and an upper redistribution substrate on the first molding layer. The second semiconductor package includes a package substrate, an upper semiconductor chip on the package substrate, and a second molding layer on the package substrate and the upper semiconductor chip.

### CROSS-REFERENCE TO RELATED APPLICATIONS

This U.S. non-provisional patent application claims priority under 35 U.S.C. § 119 to Korean Patent Application No. 10-2022-0087089, filed on Jul. 14, 2022, in the Korean Intellectual Property Office, the disclosure of which is incorporated by reference herein in its entirety.

### TECHNICAL FIELD

Exemplary embodiments of the present inventive concept relate to a semiconductor package, and more particularly, to a semiconductor package including a connection layer.

### DISCUSSION OF RELATED ART

A semiconductor package is provided to implement an integrated circuit chip to be used in electronic products. Typically, a semiconductor package is configured such that a semiconductor chip is mounted on a printed circuit board (PCB) and bonding wires or bumps are used to electrically connect the semiconductor chip to the PCB. With the advancement of electronic industry, many studies are conducted for reliability and miniaturization of semiconductor packages.

### SUMMARY

A semiconductor package according to embodiments of the inventive concept includes a first semiconductor package and a second semiconductor package disposed on the first semiconductor package. The first semiconductor package includes a lower redistribution substrate, a connection substrate disposed on the lower redistribution substrate, wherein the connection substrate includes a through hole, a first insulating layer and a through via penetrating the first insulating layer, a lower semiconductor chip disposed in the through hole, a connection layer disposed between the connection substrate and the lower redistribution substrate, wherein the connection layer includes a first metal pattern and a solder pattern disposed on the first metal pattern, a first molding layer disposed on the lower semiconductor chip and the connection substrate, and an upper redistribution substrate disposed on the first molding layer. The second semiconductor package includes a package substrate, an upper semiconductor chip disposed on the package substrate, and a second molding layer disposed on the package substrate and the upper semiconductor chip.

A semiconductor package according to embodiments of the inventive concept includes a lower redistribution substrate, a connection substrate disposed on the lower redistribution substrate, wherein the connection substrate includes a through hole, a first insulating layer, and a through via penetrating the first insulating layer, a lower semiconductor chip disposed in the through hole, wherein the lower semiconductor chip includes a lower chip body, a lower chip pad disposed on a lower surface of the lower chip body, and a connection terminal disposed under the lower chip pad, a connection layer disposed between the connection substrate and the lower redistribution substrate, wherein the connection layer includes a first metal pattern, a second metal pattern disposed on the first metal pattern, and a solder pattern disposed on the second metal pattern, a molding layer overlapping the lower semiconductor chip and the connection substrate, and an upper redistribution substrate disposed on the molding layer, wherein a lower surface of the through via is in contact with an upper surface of the solder pattern, wherein the through via has a first width measured in a first direction at a level of an upper surface of the first insulating layer and a second width measured in the first direction at a level of a lower surface of the first insulating layer, wherein the through via has a third width measured at a point inside the first insulating layer, and wherein the third width is smaller than the first width and the second width.

A semiconductor package according to embodiments of the inventive concept includes a lower redistribution substrate, a lower semiconductor chip disposed on the lower redistribution substrate, a connection substrate surrounding the lower semiconductor chip, wherein the connection substrate includes an insulating layer having a through hole and a through via penetrating the insulating layer, a connection layer disposed between the connection substrate and the lower redistribution substrate, and a molding layer disposed on the lower semiconductor chip, the connection substrate, and the connection layer, wherein the connection layer includes metal patterns and a solder pattern disposed on the metal patterns which are sequentially stacked in a region vertically overlapping the through via of the connection substrate, wherein the metal patterns, the solder pattern, and the through via vertically overlap each other, wherein the metal patterns, the solder pattern, and the through via includes materials different from each other, and wherein the through via has a shape of an hourglass in a cross-sectional view.

### BRIEF DESCRIPTION OF THE DRAWINGS

FIG. 1A is a plan view illustrating a semiconductor package according to embodiments of the inventive concept.

FIG. 1B is a cross-sectional view taken along line I-I′ of FIG. 1A illustrating a semiconductor package according to embodiments of the inventive concept.

FIG. 2A is an enlarged view corresponding to portion “A” of FIG. 1B of the semiconductor package according to embodiments of the inventive concept.

FIG. 2B is an enlarged view corresponding to portion “B” of FIG. 1B of the semiconductor package according to embodiments of the inventive concept.

FIGS. 3A, 3B, 3C, 3D, 3E, 3F, 3G, 3H, and 3I are cross-sectional views illustrating a process of manufacturing the semiconductor package of FIG. 1B according to embodiments of the inventive concept.

FIG. 4 is a cross-sectional view taken along line I-I′ of FIG. 1A illustrating a semiconductor package according to some embodiments of the inventive concept.

FIG. 5 is a cross-sectional view taken along line I-I′ of FIG. 1A illustrating a semiconductor package according to some embodiments of the inventive concept.

### DETAILED DESCRIPTION

Hereinafter, the inventive concept is described in more detail. Embodiments according to the inventive concept will be described in more detail with reference to the accompanying drawings.

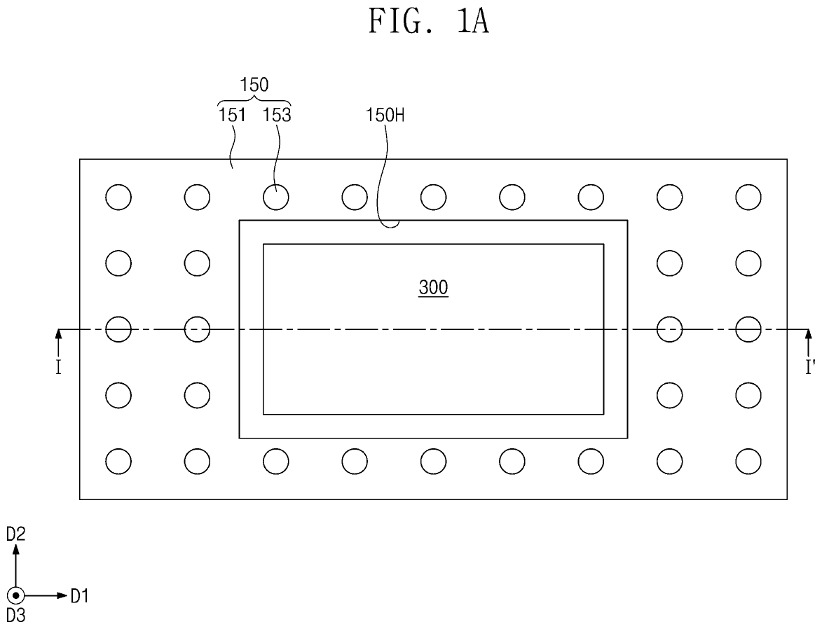

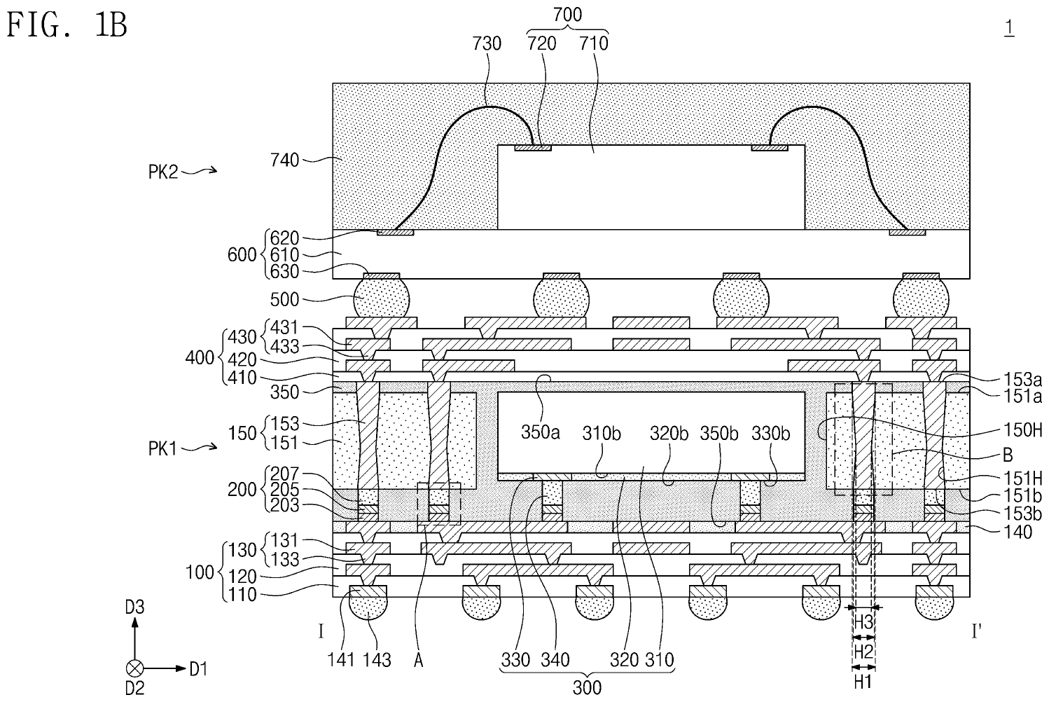

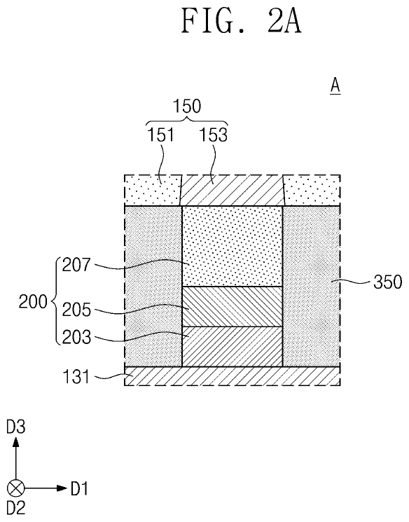

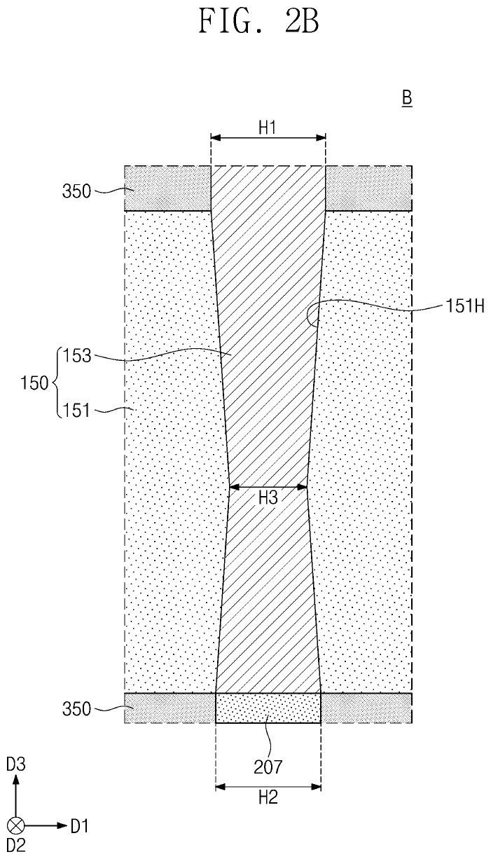

FIG. 1A is a plan view illustrating a semiconductor package according to embodiments of the inventive concept. FIG. 1B is a cross-sectional view taken along line I-I′ of FIG. 1A illustrating a semiconductor package according to embodiments of the inventive concept. FIG. 2A is an enlarged view corresponding to portion “A” of FIG. 1B of the semiconductor package according to embodiments of the inventive concept. FIG. 2B is an enlarged view corresponding to portion “B” of FIG. 1B of the semiconductor package according to embodiments of the inventive concept.

Referring to FIGS. 1A, 1B, 2A, and 2B, semiconductor package 1 includes a first semiconductor package PK1 and a second semiconductor package PK2 disposed on the first semiconductor package PK1.

The first semiconductor package PK1 includes a lower redistribution substrate 100, a connection substrate 150, connection patterns 200, a lower semiconductor chip 300, a first molding layer 350, and an upper redistribution substrate 400.

According to embodiments of the present inventive concept, the lower redistribution substrate 100 and the upper redistribution substrate 400 should not be understood as a conventional printed circuit board (PCB). For example, the lower redistribution substrate 100 and the upper redistribution substrate 400 might not include a core layer in which glass fibers are impregnated with an epoxy compound.

The lower redistribution substrate 100 includes a first passivation layer 110, a lower redistribution insulating layer 120, and lower redistribution patterns 130.

As used herein, a first direction D1 is defined as a direction parallel to an upper surface of the lower redistribution substrate 100. A second direction D2 is defined as a direction that crosses the first direction D1 and is parallel to the upper surface of the lower redistribution substrate 100. A third direction D3 is defined as a direction perpendicular to the upper surface of the lower redistribution substrate 100.

An under bump pattern 141 may be disposed in the first passivation layer 110. In some embodiments, the under bump pattern 141 may be provided in plurality. In some cases, the under bump pattern 141 may include copper (Cu). The first passivation layer 110 may include at least one of a photosensitive polyimide, polybenzoxazole, a phenol-based polymer, and a benzocyclobutene-based polymer.

The lower redistribution insulating layer 120 may be disposed on the first passivation layer 110. In some embodiments, a plurality of lower redistribution insulating layer 120 may be disposed on the first passivation layer 110. Although only two lower redistribution insulating layers 120 are illustrated in the figures, the inventive concept is not limited thereto. In some cases, the semiconductor package 1 may include less than two or more than two lower redistribution insulating layers 120. According to some embodiments, there may be no measurable interface between the first passivation layer 110 and a lowermost surface of the lower redistribution insulating layers 120, and between the lower redistribution insulating layers 120. For example, the first passivation layer 110 and the lower redistribution insulating layers 120 may be considered as one insulating layer. The lower redistribution insulating layer 120 may include at least one of a photosensitive polyimide, polybenzoxazole, a phenol-based polymer, and a benzocyclobutene-based polymer.

The lower redistribution patterns 130 may be disposed in the lower redistribution insulating layers 120. In some embodiments, the lower redistribution patterns 130 are vertically disposed on top of each other. The lower redistribution patterns 130 may include a lower redistribution wiring portion 131 and a lower redistribution via portion 133 that are integrally connected. The lower redistribution via portion 133 may be disposed at a lowermost portion of the lower redistribution patterns 130. In some embodiments, the lower redistribution via portion 133 may partially penetrate the first passivation layer 110 and in contact with the under bump pattern 141. In some cases, the lower redistribution patterns 130 may include copper (Cu). In some embodiments, the lower redistribution patterns 130 may further include a seed/barrier pattern. The seed/barrier pattern may be locally disposed on the bottom surface of the lower redistribution patterns 130. Alternatively, the seed/barrier pattern may be locally disposed on the bottom surface of the lower redistribution via portion 133. In some cases, the seed/barrier pattern may include, for example, copper or titanium.

A first insulating layer 140 may be disposed on uppermost ones of the lower redistribution patterns 130. Alternatively, the first insulating layer 140 may be disposed between the lower redistribution insulating layer 120 and connection patterns 200. In some embodiments, a top surface of the first insulating layer 140 may be coplanar with top surfaces of the uppermost ones of the lower redistribution patterns 130. The first insulating layer 140 may include an insulating material, for example, Ajinomoto build-up film (ABF).

According to some embodiments of the present inventive concept, the connection substrate 150 including a through hole 150H may be disposed on the lower redistribution substrate 100. The connection substrate 150 may be, for example, an embedded trace substrate (ETS). The connection substrate 150 may include a second insulating layer 151 and a through-via 153 penetrating the second insulating layer 151.

The second insulating layer 151 may include the through-via hole 151H. In some cases, a plurality of through-via holes 151H may be disposed in the second insulating layer 151. The second insulating layer 151 may include an insulating resin. According to an embodiment, the second insulating layer 151 may include at least one of polyhydroxystyrene (PHS), polybenzoxazole (PBO), and polypropylene glycol (PPG).

A through-via 153 may be disposed in the through-via hole 151H. In some cases, a plurality of through vias 153 may be disposed in the through-via hole 151H. Each of the through vias 153 may be spaced apart from each other in the first direction D1 and the second direction D2.

Hereinafter, one through-via 153 will be described, but the description may be applied to all of the plurality of through-vias 153. A side surface of the through via 153 may be in contact with the second insulating layer 151. According to an embodiment, a level of an upper surface 153a of the through-via 153 may be higher than a level of an upper surface 151a of the second insulating layer 151. According to an embodiment, a level of a lower surface 153b of the through-via 153 may be the same as a level of a lower surface 151b of the second insulating layer 151. The through-via 153 may include a conductive material, for example, copper (Cu).

As shown in FIG. 2B, the through-via 153 may have a first width H1 measured in the first direction D1 at the same level as the level of the upper surface 151a of the second insulating layer 151. In some embodiments, through-via 153 may have a first width H1 measured in the first direction D1 at the same level as the level of the upper surface 153a of the through-via 153. The through-via 153 may have a second width H2 measured in the first direction D1 at the same level as the level of the lower surface 153b of the through-via 153. The through via 153 may have a third width H3 measured in the first direction D1 at a certain point inside the second insulating layer 151 along the third direction D3. The first width H1 and the second width H2 may be greater than the third width H3. For example, the width of the through-via 153 measured in the first direction D1 may decrease from both ends toward a center of the through-via 153 along the third direction D3. The width of the through via 153 measured in the first direction D1 may first decrease and then increase from the upper surface 151a of the second insulating layer 151 to the lower surface 151b of the second insulating layer 151. For example, in the cross-sectional view shown in FIG. 1B, the through-via 153 may have a shape of an hourglass.

As shown in FIG. 1B, the connection patterns 200 may be disposed between the lower redistribution substrate 100 and the connection substrate 150. The connection patterns 200 may also be disposed between the lower redistribution substrate 100 and the lower semiconductor chip 300 (which will be described in later sections). The connection patterns 200 may include a first metal pattern 203, a second metal pattern 205, and a solder pattern 207 that are sequentially stacked. An enlarged view on the structure of the connection patterns 200 is shown in FIG. 2A. Among the connection patterns 200, the connection patterns 200 disposed between the lower redistribution substrate 100 and the lower semiconductor chip 300 (to be described later) might not include the solder pattern 207.

Some of the connection patterns 200 may overlap each of corresponding through-vias 153 in the third direction D3. The remaining portions of the connection patterns 200 may overlap the lower semiconductor chip 300 (to be described later) in the third direction D3. The first metal pattern 203 may be in contact with an uppermost one of the lower redistribution patterns 130. In some cases, the first metal pattern 203 may be in contact with an upper surface of the uppermost lower redistribution wiring portion 131. The first metal pattern 203 may include, for example, nickel (Ni).

The second metal pattern 205 may be disposed on the first metal pattern 203. In some cases, the second metal pattern 205 may be disposed between the first metal pattern 203 and the solder pattern 207. A lower surface of the second metal pattern 205 may be in contact with an upper surface of the first metal pattern 203. The second metal pattern 205 may include, for example, gold (Au).

The solder pattern 207 may be disposed on the second metal pattern 205. The lower surface of the solder pattern 207 may be in contact with an upper surface of the second metal pattern 205. The solder pattern 207 may be disposed on a portion that vertically overlaps the through via 153. In some embodiments, solder pattern 207 might not be disposed between the lower redistribution substrate 100 and the lower semiconductor chip 300 (to be described later). The upper surface of the solder pattern 207 may be in contact with the lower surface 153b of the through via 153. The solder pattern 207 may include a solder material, for example, at least one of tin (Sn) or a tin-silver (Sn—Ag) alloy.

According to embodiments of the inventive concept, the connection patterns 200 may be disposed on the lower redistribution substrate 100, and each of the connection patterns 200 that vertically overlaps the connection substrate 150 among the connection patterns 200 may be include the solder pattern 207 including tin or a tin-silver alloy. Accordingly, the connection substrate 150 including the second insulating layer 151 and the through vias 153 may be separately manufactured and attached to the connection patterns 200, and thus a photo process for manufacturing a conductive structure connecting the lower redistribution substrate 100 and the upper redistribution substrate 400 may be omitted. Therefore, there may be no need to use a photoresist material, and thus deterioration of electrical characteristics of the semiconductor package 1 caused by the residual photoresist material may be prevented. Accordingly, reliability of the semiconductor package 1 may be improved.

In addition, omitting the photo process may reduce process steps, and manufacturing cost (such as time and resources) of the semiconductor package 1 may be reduced.

According to some embodiments, thicknesses of the first metal patterns 203 and the second metal patterns 205 measured in the third direction D3 may be substantially the same as each other. In an embodiment, thicknesses of the first metal patterns 203 and second metal patterns 205 measured in the third direction D3 may be different from each other. For example, a thickness of the solder pattern 207 measured in the third direction D3 may be greater than a thickness of the first metal patterns 203 and the second metal patterns 205. The thickness of the solder pattern 207 measured in the third direction D3 may be equal to or smaller than the thickness of the first metal patterns 203 and second metal patterns 205. The thicknesses may vary depending on a design of the semiconductor package 1 to be manufactured.

According to some embodiments, widths of the first metal patterns 203 and the second metal patterns 205 measured in the first direction D1 or the second direction D2 may be substantially the same as each other. For example, sidewalls of the first metal patterns 203 and the second metal patterns 205 may be aligned when viewed in the first direction or the second direction. As an example, widths of the first metal patterns 203 and the second metal patterns 205 measured in the first direction D1 or the second direction D2 may be different from each other. For example, sidewalls of the first metal patterns 203 and second metal patterns 205 might not be aligned when viewed in the first direction or the second direction. A width of the solder pattern 207 measured in the first direction D1 or the second direction D2 may be substantially equal to a width of the first metal patterns 203 and the second metal patterns 205 measured in the first direction D1 or the second direction D2. According to an embodiment, the width of the solder pattern 207 measured in the first direction D1 or the second direction D2 may be greater or smaller than a width of the first metal patterns 203 and the second metal patterns 205 measured in the first direction D1 or the second direction D2. The widths may vary depending on a design of the semiconductor package 1 to be manufactured.

The through via 153 may be electrically connected to the lower redistribution patterns 130 through the solder pattern 207, second metal patterns 205, and the first metal patterns 203. For example, the through via 153 may be electrically connected to the lower redistribution substrate 100.

The lower semiconductor chip 300 may be disposed in the through hole 150H of the connection substrate 150. The lower semiconductor chip 300 may be spaced apart from the connection substrate 150 in first direction D1 and second direction D2. The lower semiconductor chip 300 may be disposed on some of the connection patterns 200. The lower semiconductor chip 300 may be, for example, a logic chip.

The lower semiconductor chip 300 may include a lower chip body 310, a lower chip passivation layer 320, a lower chip pad 330, and a first connection terminal 340.

The lower chip body 310 may be a semiconductor substrate including silicon, germanium, silicon-germanium, or the like, or a compound semiconductor substrate. For example, the lower chip body 310 may be a silicon substrate.

The lower chip passivation layer 320 may be disposed on a lower surface 310b of the lower chip body 310. The lower chip passivation layer 320 may cover or overlap the lower surface 310b of the lower chip body 310. The lower chip passivation layer 320 may cover or overlap a side surface of the lower chip pad 330, which will be described later, but might not cover or overlap a lower surface 330b of the lower chip pad 330. For example, a lower surface of the lower chip passivation layer 320 is coplanar with a lower surface of the lower chip pad 330. In some embodiments, a level of a lower surface 320b of the lower chip passivation layer 320 may be higher than a level of the lower surface 151b of the second insulating layer 151. The lower chip passivation layer 320 may include an insulating material, for example, an oxide layer, a nitride layer, or a double layer thereof.

The lower chip pad 330 may be disposed on the lower surface 310b of the lower chip body 310. For example, a lower surface 330b of the lower chip pad 330 may be coplanar with the lower surface 320b of the lower chip passivation layer 320. In some embodiments, a level of the lower surface 330b of the lower chip pad 330 may be higher than a level of the lower surface 320b of the lower chip passivation layer 320. The level of the lower surface 330b of the lower chip pad 330 may be higher than the level of the lower surface 151b of the second insulating layer 151. The lower chip pad 330 may include a conductive material, for example, aluminum (Al).

The first connection terminal 340 may be disposed on the lower surface 330b of the lower chip pad 330. The first connection terminal 340 may be disposed between the lower chip pad 330 and the second metal pattern 205. The first connection terminal 340 may be in contact with the lower chip pad 330 and the second metal pattern 205. Alternatively, the lower chip pad 330 may be electrically connected to the lower chip pad 330 and the second metal pattern 205. Accordingly, the lower semiconductor chip 300 may be electrically connected to the lower redistribution substrate 100. The first connection terminal 340 may include a solder material, for example, at least one of solder, pillar, and bump. For example, the first connection terminal 340 may include a conductive material such as tin (Sn) or silver (Ag). As an example, the first connection terminal 340 may include substantially the same material as the solder pattern 207.

As shown in FIG. 1B, the first molding layer 350 may cover or overlap the connection substrate 150, the lower semiconductor chip 300, the lower redistribution substrate 100, the first insulating layer 140, and the connection patterns 200. The first molding layer 350 may cover or overlap an upper surface of the first insulating layer 140. The first molding layer 350 may cover or overlap the upper surface 151a, the lower surface 151b, and the side surface of the second insulating layer 151. A level of an upper surface 350a of the first molding layer 350 may be higher than the level of the upper surface 151a of the second insulating layer 151. The first molding layer 350 may cover or overlap a portion of a side surface of an upper portion of the through via 153. The first molding layer 350 might not cover or overlap the upper surface 153a of the through via 153. An upper surface 350a of the first molding layer 350 may be coplanar with the upper surface 153a of the through-via 153. The first molding layer 350 may cover or overlap an upper surface and a side surface of the lower chip body 310. The first molding layer 350 may cover or overlap the side surface and the lower surface 320b of the lower chip passivation layer 320. The first molding layer 350 may cover or overlap a portion of the lower surface 330b of the lower chip pad 330. For example, the first molding layer 350 may further cover or overlap a portion of a side surface of the lower chip pad 330. The first molding layer 350 may cover or overlap a side surface of the first connection terminal 340. The first molding layer 350 may cover or overlap side surfaces of the connection patterns 200. The first molding layer 350 may fill the through hole 150H of the connection substrate 150. The first molding layer 350 may be disposed between the connection substrate 150 and the lower semiconductor chip 300. The first molding layer 350 may be disposed between the lower semiconductor chip 300 and the lower redistribution substrate 100, and between the connection substrate 150 and the lower redistribution substrate 100.

The first molding layer 350 may include a material different from a material of the second insulating layer 151. The first molding layer 350 may include a thermosetting resin such as an epoxy resin or a thermoplastic resin such as polyimide. Alternatively, the first molding layer 350 may include a resin having a reinforcing material impregnated in the thermosetting resin and the thermoplastic resin, such as Ajinomoto build-up film (ABF), FR-4, or BT. Alternatively, the first molding layer 350 may include a molding material such as epoxy molding compound (EMC) or a photosensitive material such as photo imaginable encapsulant (PIE). For example, the first molding layer 350 may include ABF.

The upper redistribution substrate 400 may be disposed on the first molding layer 350. The upper redistribution substrate 400 may cover or overlap the upper surface 350a of the first molding layer 350 and the upper surface 153a of the through vias 153.

The upper redistribution substrate 400 may include a second passivation layer 410, an upper redistribution insulating layer 420, and upper redistribution patterns 430.

The second passivation layer 410 may be disposed at a lowermost portion of the upper redistribution substrate 400. A lower surface of the second passivation layer 410 may be in contact with the upper surface 350a of the first molding layer 350 and the upper surface 153a of the through vias 153. The second passivation layer 410 may include at least one of a photosensitive polyimide, polybenzoxazole, a phenol-based polymer, and a benzocyclobutene-based polymer.

The upper redistribution insulating layer 420 may be disposed on the second passivation layer 410. A plurality of upper redistribution insulating layers 420 may be disposed on the second passivation layer 410. The plurality of upper redistribution insulating layers 420 may be sequentially stacked and may have a measurable interface. Although only two upper redistribution insulating layers 420 are illustrated in the figures, the inventive concept is not limited thereto. In some cases, the semiconductor package 1 may include less than two or more than two upper redistribution insulating layers. According to some embodiments, there may be no measurable interface between the second passivation layer 410 and the lowermost layer of the upper redistribution insulating layers 420, and between the plurality of upper redistribution insulating layers 420. For example, the second passivation layer 410 and the upper redistribution insulating layers 420 may be considered as one insulating layer. The upper redistribution insulating layer 420 may include at least one of photosensitive polyimide, polybenzoxazole, a phenol-based polymer, and a benzocyclobutene-based polymer.

The upper redistribution patterns 430 may be disposed in upper redistribution insulating layers 420. The upper redistribution patterns 430 may include an upper redistribution wiring portion 431 and an upper redistribution via portion 433 that are integrally connected. The upper redistribution via portion 433 is disposed at a lowermost portion of the upper redistribution patterns 430. The upper redistribution via portion 433 may penetrate the second passivation layer 410 and be in contact with the upper surfaces 153a of the through vias 153. Accordingly, the upper redistribution patterns 430 may be electrically connected to the through vias 153. Additionally, the upper redistribution patterns 430 may be electrically connected to the first passivation layer 110. The upper redistribution patterns 430 may include copper (Cu). In some embodiments, the upper redistribution patterns 430 may further include a seed/barrier pattern. The seed/barrier pattern may be locally disposed on the bottom surface of the upper redistribution patterns 430. The seed/barrier pattern may include copper (Cu) or titanium (Ti).

According to embodiments of the present inventive concept, the second semiconductor package PK2 may be disposed on the first semiconductor package PK1. The second semiconductor package PK2 may include a second connection terminal 500, a package substrate 600, an upper semiconductor chip 700, a metal wire 730, and a second molding layer 740.

The second connection terminal 500 may be disposed on the upper redistribution substrate 400. The second connection terminal 500 may be in contact with an uppermost one of the upper redistribution wiring portion 431 of the upper redistribution patterns 430. The second connection terminal 500 may be electrically connected to the upper redistribution patterns 430. The second connection terminal 500 may include a solder material, for example, at least one of solder, pillar, and bump. The second connection terminal 500 may include a conductive material such as tin (Sn) or silver (Ag).

The package substrate 600 may be disposed on the second connection terminal 500. The package substrate 600 may be spaced apart from the upper redistribution substrate 400 in the third direction D3 with the second connection terminal 500 interposed therebetween. For example, second connection terminal 500 may be disposed between the package substrate 600 and the upper redistribution substrate 400. The package substrate 600 may include a package body 610, an upper metal pad 620, and a lower metal pad 630.

The package substrate 600 may be a printed circuit board (PCB) or a redistribution board. The lower metal pad 630 may be in contact with the second connection terminal 500. Alternatively, the lower metal pad 630 may be disposed on the second connection terminal 500. Accordingly, the package substrate 600 may be electrically connected to the second connection terminal 500. Additionally, the package substrate 600 may be electrically connected to the upper redistribution substrate 400 through the second connection terminal 500. The upper metal pad 620 and the lower metal pad 630 may include a metal material, for example, aluminum (Al).

According to embodiments of the present inventive concept, upper semiconductor chip 700 may be disposed on the package substrate 600. The upper semiconductor chip 700 may be, for example, a memory chip such as DRAM or NAND flash. In some cases, upper semiconductor chip 700 may be a different type of semiconductor chip from the lower semiconductor chip 300. The upper semiconductor chip 700 may include an upper chip body 710 and an upper chip pad 720 disposed on a top surface of the upper chip body 710.

In some embodiments, upper chip body 710 may be a semiconductor substrate including silicon, germanium, silicon-germanium, or the like, or a compound semiconductor substrate. For example, the upper chip body 710 may be a silicon substrate.

The upper chip pad 720 may be connected to the upper metal pad 620 of the package substrate 600 by wire bonding through the metal wire 730. Accordingly, the upper semiconductor chip 700 may be electrically connected to the package substrate 600. The upper chip pad 720 may include a metal material, for example, aluminum (Al).

According to some embodiments, second molding layer 740 is disposed on upper semiconductor chip 700 and the package substrate 600. The second molding layer 740 may cover or overlap the upper surface and the side surface of the upper semiconductor chip 700. The second molding layer 740 may cover or overlap a portion of the top surface of the package substrate 600. A sidewall of the second molding layer 740 may be aligned with a sidewall of the package substrate 600. The second molding layer 740 may include a thermosetting resin such as an epoxy resin or a thermoplastic resin such as polyimide. Alternatively, the second molding layer 740 may include a resin having a reinforcing material impregnated in the thermosetting resin and the thermoplastic resin, such as Ajinomoto build-up film (ABF), FR-4, BT. Alternatively, the second molding layer 740 may include a molding material such as epoxy molding compound (EMC) or a photosensitive material such as photo imaginable encapsulant (PIE). For example, the second molding layer 740 may include ABF.

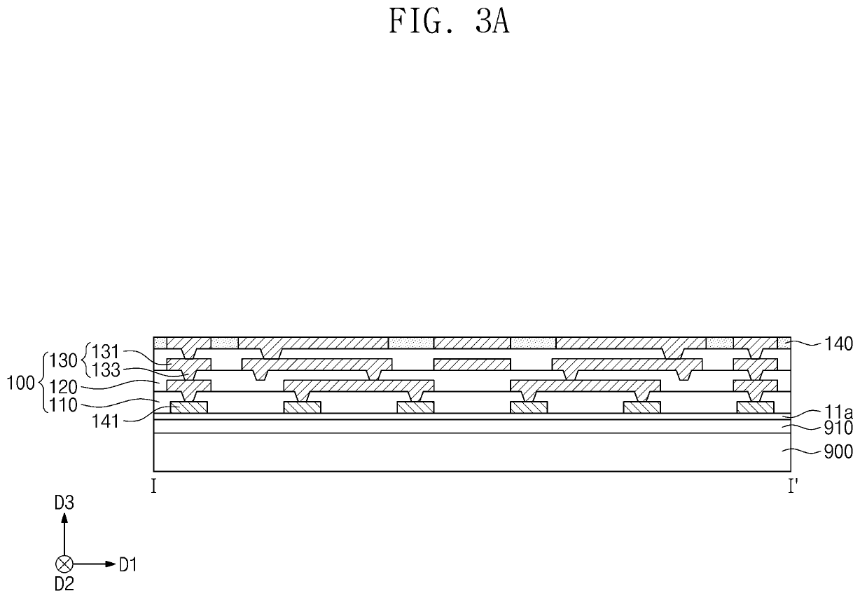

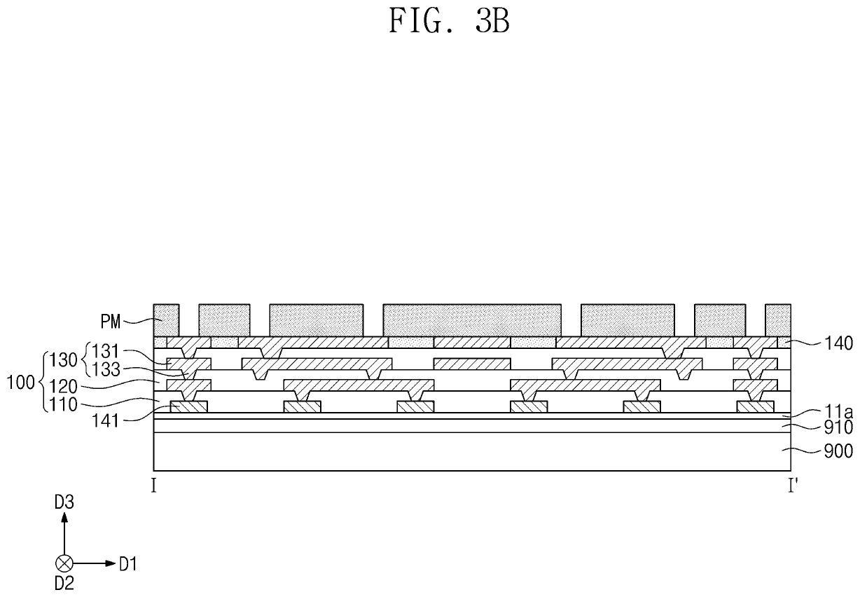

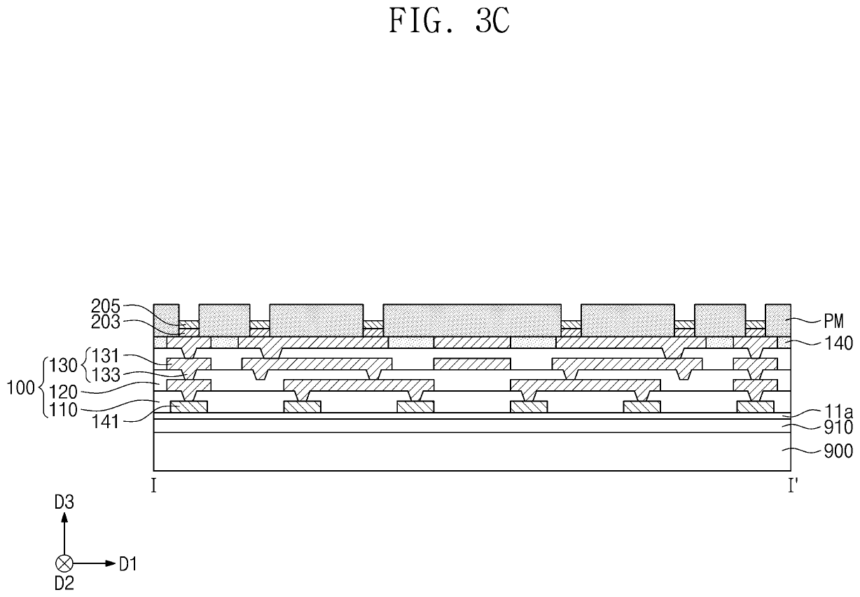

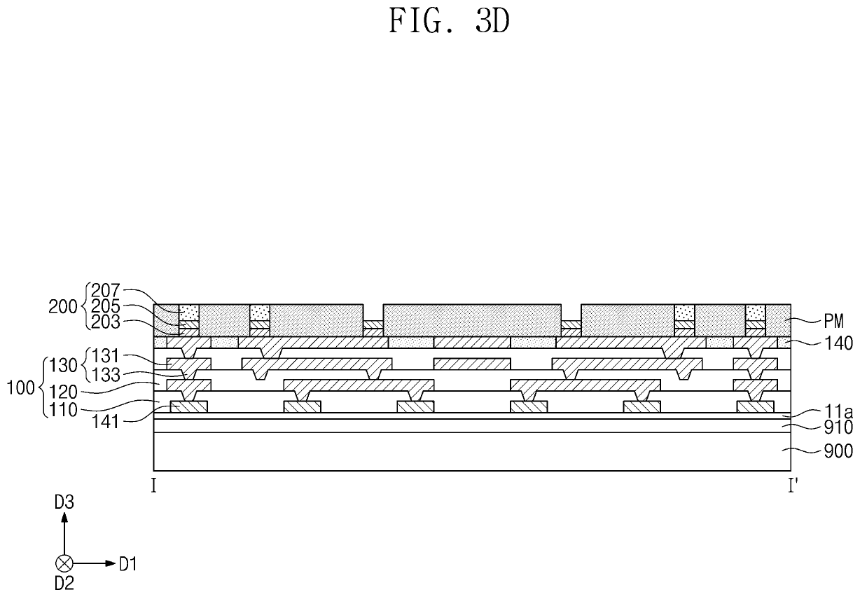

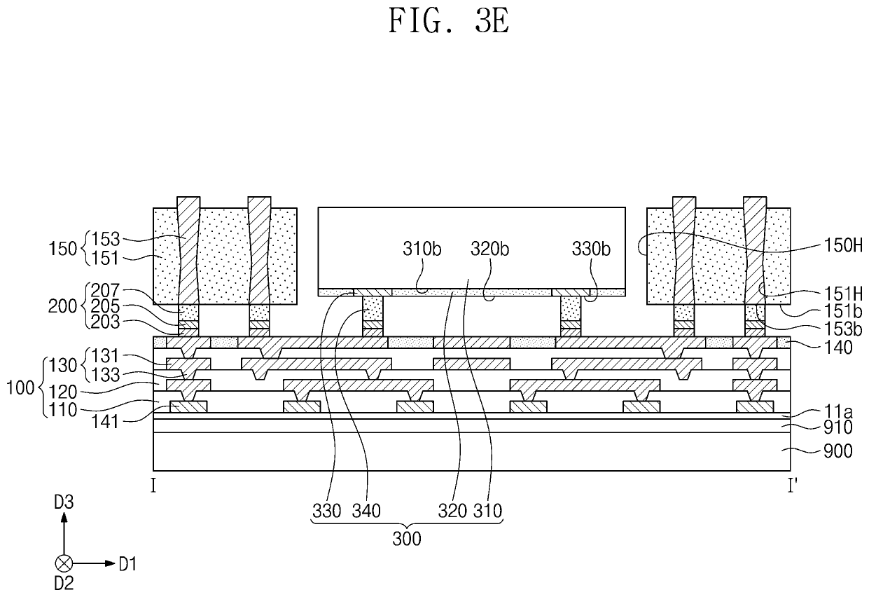

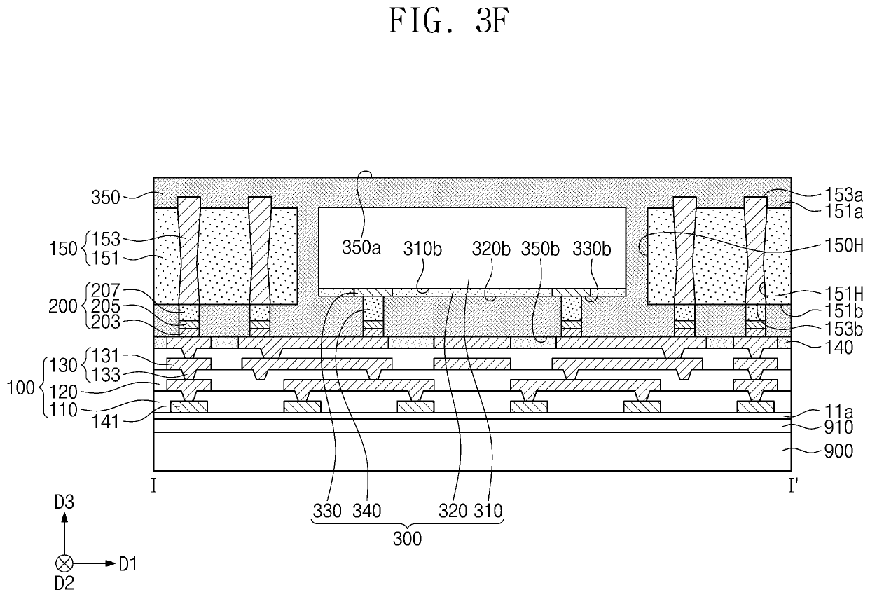

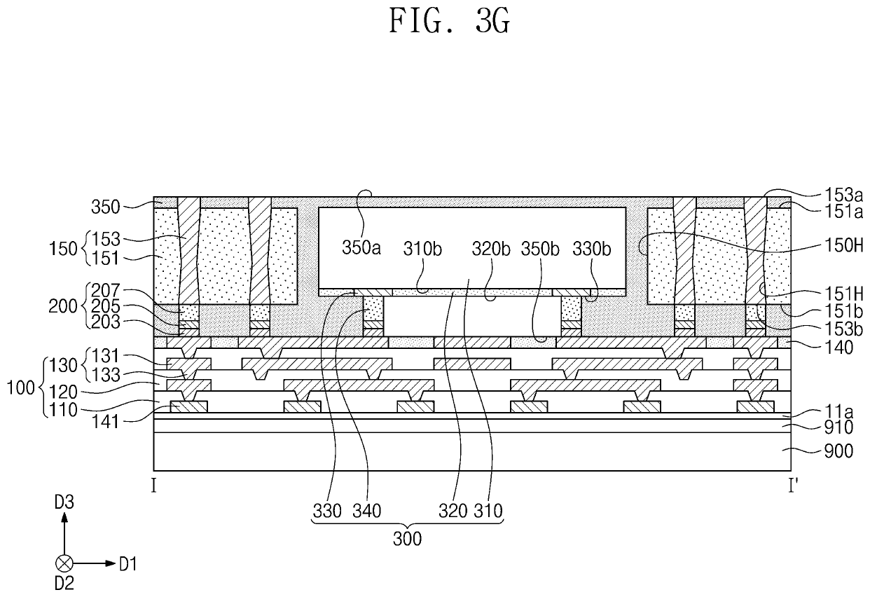

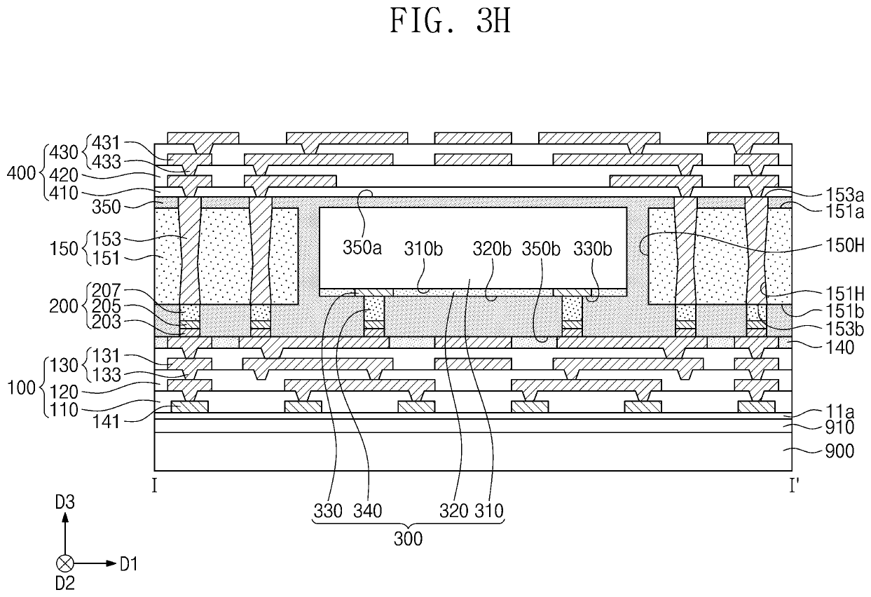

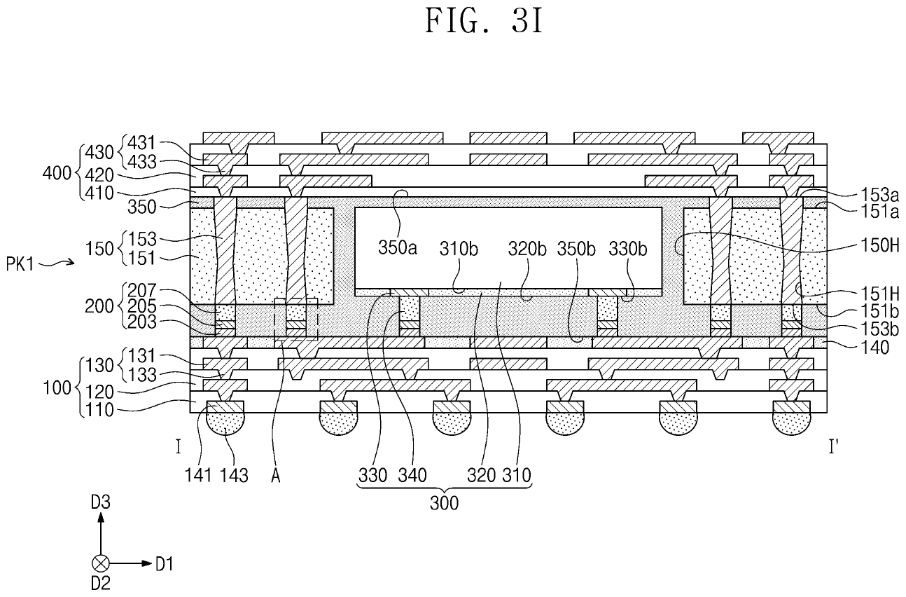

FIGS. 3A to 3I are cross-sectional views illustrating a process of manufacturing the semiconductor package of FIG. 1B according to embodiments of the inventive concept. Hereinafter, a method of manufacturing the semiconductor package 1 will be described in detail with reference to FIGS. 3A to 3I.

Referring to FIG. 3A, a carrier substrate 900 having an adhesive layer 910 formed on a top surface thereof may be provided. A seed layer 11a may be formed on the carrier substrate 900 to cover or overlap an upper surface of the adhesive layer 910. The seed layer 11a may be formed by a deposition process. The adhesive layer 910 may attach the seed layer 11a to the carrier substrate 900. A photomask pattern including an opening defining a space for forming a under bump pattern 141 may be formed through forming a photoresist layer, exposing, and developing. The seed layer 11a may be exposed by the photomask pattern. The under bump pattern 141 may be formed by performing an electroplating process using the seed layer 11a as an electrode in the opening. Thereafter, the photomask pattern may be removed, and a first passivation layer 110 covering or overlapping the under bump pattern 141 may be formed. For example, the first passivation layer 110 is formed on the under bump pattern 141. The first passivation layer 110 may be formed by a coating process such as spin coating or slit coating.

Lower redistribution insulating layers 120 and lower redistribution patterns 130 may be formed on the first passivation layer 110. The lower redistribution insulating layers 120 may be formed by a coating process such as spin coating or slit coating. The lower redistribution patterns 130 may be formed in a manner similar to the method in which the under bump pattern 141 is formed. In some embodiments, one or more lower redistribution insulating layers 120 and lower redistribution patterns 130 may be formed on the first passivation layer 110.

A first insulating layer 140 covering or overlapping a side surface of the lower redistribution pattern 130 disposed on an uppermost portion of the lower redistribution patterns 130 may be formed. In detail, an insulating film may be formed to cover or overlapping upper and side surfaces of the lower redistribution pattern 130 disposed on the uppermost portion. Then, a portion of the insulating film may be removed to expose the upper surface of the lower redistribution pattern 130, and the first insulating layer 140 may be formed. For example, a top surface of the first insulating layer 140 is coplanar with a top surface of the uppermost portion of the lower redistribution patterns 130.

Referring to FIG. 3B, a photomask may be formed on the first insulating layer 140 and on an uppermost one of the lower redistribution patterns 130. A photo process may be performed on the photomask to form a photomask pattern PM. As a result, portions of the uppermost surface of the lower redistribution patterns 130 are not covered by the photomask and openings are formed.

Referring to FIG. 3C, the first metal patterns 203 and the second metal patterns 205 may be formed sequentially in each of openings of the photomask pattern PM. For example, the first metal patterns 203 is disposed on the lower redistribution patterns 130. The second metal patterns 205 is disposed on the first metal patterns 203. The first metal pattern 203 and the second metal pattern 205 may be formed through an electroless plating method (chemical plating method).

Referring to FIG. 3D, a solder pattern 207 may be formed on the second metal pattern 205. The solder pattern 207 may be formed using vacuum deposition, screen printing, stud bumping bonding, or electroless plating. The solder pattern 207 might not be formed on a portion overlapping the lower semiconductor chip 300 to be manufactured. Alternatively, the connection pattern 200 includes the first metal patterns 203, the second metal patterns 205, and the solder pattern 207.

Referring to FIG. 3E, a connection substrate 150 may be formed on a connection patterns 200. Forming the connection substrate 150 may include forming a through-via hole 151H using a laser drill on an upper surface 151a and a lower surface 151b of a second insulating layer 151. Through-via 153 is formed in the through-via hole 151H using an electroplating method. Through-via 153 attaches the connection substrate 150 including the second insulating layer 151 and the through-via hole 151H on the connection patterns 200.

Thereafter, a lower semiconductor chip 300 may be disposed in the through hole 150H of the connection substrate 150 and may be mounted on the lower redistribution substrate 100. For example, the first connection terminal 340 of the lower semiconductor chip 300 is disposed on the second metal pattern 205. In some embodiments, the photomask pattern PM may be removed.

Referring to FIG. 3F, a first molding layer 350 covering or overlapping the connection substrate 150, the lower semiconductor chip 300, and the connection patterns 200 may be formed. A level of a top surface 350a of the first molding layer 350 may be higher than a top surface 153a of through vias 153.

Referring to FIG. 3G, a planarization process may be performed on the first molding layer 350 until the top surface of the through via 153 is exposed. The planarization process may use chemical-mechanical polishing (CMP). Due to the planarization process, the upper surface 350a of the first molding layer 350 and the upper surface 153a of the through via 153 may be coplanar with each other. In some cases, a portion of the upper portion of the through via 153 may be removed.

Referring to FIG. 3H, an upper redistribution substrate 400 may be formed on the first molding layer 350 and the through vias 153. A second passivation layer 410 of the upper redistribution substrate 400 may be formed by the same method as the method of forming the first passivation layer 110 of the lower redistribution substrate 100. An upper redistribution insulating layers 420 and an upper redistribution patterns 430 of the upper redistribution substrate 400 may be formed by the same method of the method of forming the lower redistribution insulating layers 120 and the lower redistribution patterns 130 of the lower redistribution substrate 100, respectively.

Referring to FIG. 3I, the carrier substrate 900, the adhesive layer 910, and the seed layer 11a may be removed. Thereafter, external connection terminals 143 may be formed below the under bump patterns 141. Accordingly, a first semiconductor package PK1 may be formed.

Referring back to FIG. 1B, a second semiconductor package PK2 may be formed on the first semiconductor package PK1. Forming the second semiconductor package PK2 may include forming a second connection terminal 500 on the upper redistribution substrate 400, forming a package substrate 600 on the second connection terminal 500, forming a second semiconductor chip 700 and a metal wire 730 on the package substrate 600, and forming a second molding layer 740. Accordingly, a semiconductor package 1 may be manufactured.

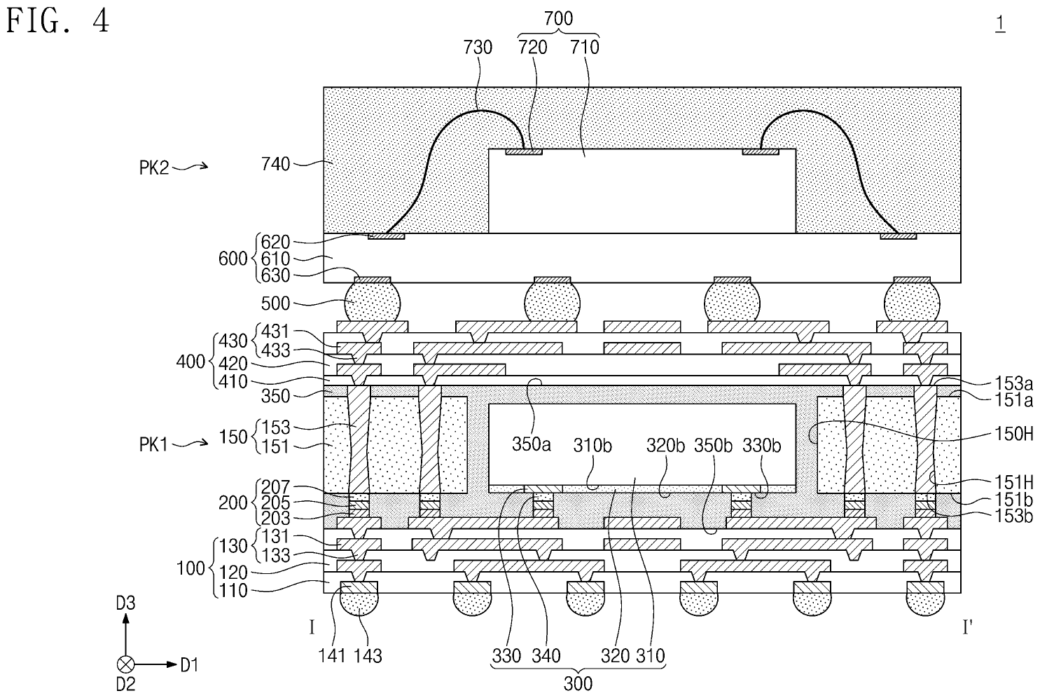

FIG. 4 is a cross-sectional view taken along line I-I′ of FIG. 1A illustrating a semiconductor package according to some embodiments of the inventive concept. Hereinafter, descriptions overlapping those described with reference to FIGS. 1A to 2B may be omitted, and omitted details are understood to be the same as described for corresponding elements elsewhere in the disclosure.

Referring to FIG. 4, the first insulating layer 140 of FIG. 1B might not be provided. The first molding layer 350 may cover or overlap side surfaces of the first and second metal patterns 203 and 205 and the solder pattern 207. The first molding layer 350 may cover or overlap an uppermost one of the lower redistribution insulating layers 120 and an uppermost one of the lower redistribution patterns 130. The first molding layer 350 may be disposed between the connection substrate 150 and the lower redistribution substrate 100. Compared to FIG. 1B, in FIG. 4, a thickness of the solder pattern 207 measured in the third direction D3 and a thickness of the first connection terminal 340 measured in the third direction D3 are reduced, but this is not limited thereto. In some embodiments, the thickness of the solder pattern 207 measured in the third direction D3 and the thickness of the first connection terminal 340 measured in the third direction D3 may be the same as those in FIG. 1B. For example, a level of the lower surface 320b of the lower chip passivation layer 320 may be coplanar with lower surface 151b of the second insulating layer 151.

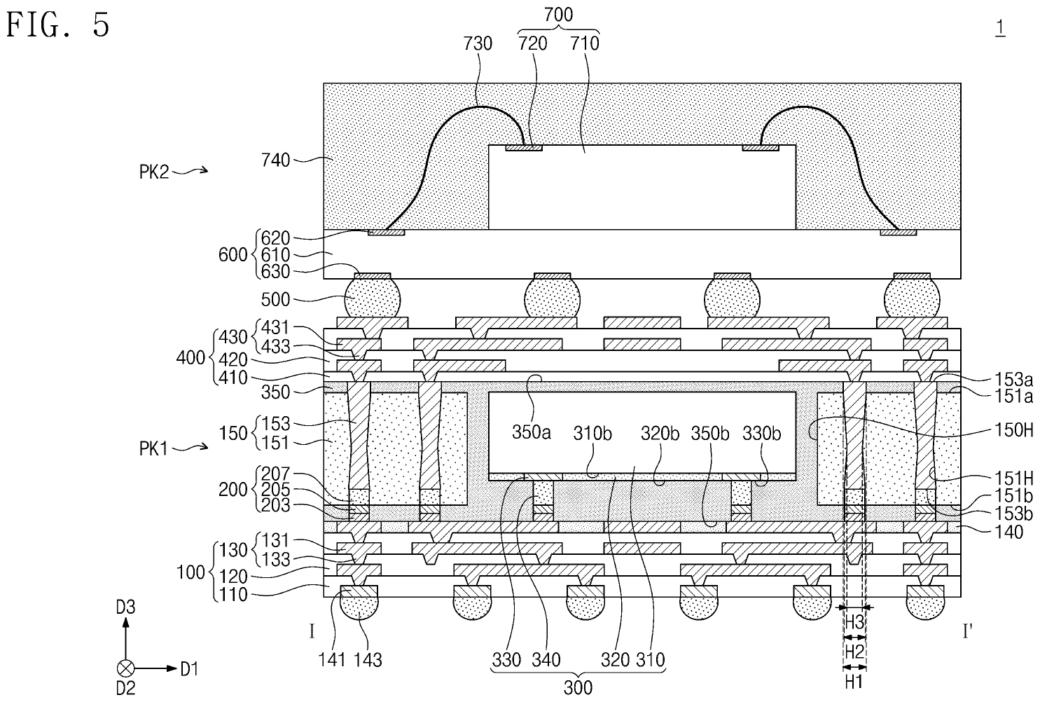

FIG. 5 is a cross-sectional view taken along line I-I′ of FIG. 1A illustrating a semiconductor package according to some embodiments of the inventive concept. Hereinafter, descriptions overlapping those described with reference to FIGS. 1A to 2B may be omitted, and omitted details are understood to be the same as described for corresponding elements elsewhere in the disclosure.

Referring to FIG. 5, the second insulating layer 151 may cover or overlap the side surface of the solder pattern 207. The solder pattern 207 might not be in contact with the first molding layer 350. For example, the solder pattern 207 may be spaced apart from the first molding layer 350. The first molding layer 350 may cover or overlap a side surface of the first connection terminal 340. The lower surface 151b of the second insulating layer 151 may be coplanar with the lower surface of the solder pattern 207.

According to the inventive concept, the connection layer may be disposed on the lower redistribution substrate, and the connection layer may include the solder pattern including tin or a tin-silver alloy. Accordingly, the connection substrate including the insulating layer and through-vias may be separately manufactured and attached to the connection layer, and thus the photo process for manufacturing the conductive structure connecting the lower redistribution substrate and the upper redistribution substrate may be omitted. Accordingly, to the use of a photoresist material may be avoided, and thus the deterioration of electrical characteristics of the semiconductor package caused by the remaining photoresist material may be prevented. Accordingly, the reliability of the semiconductor package may be improved.

In addition, the process steps may be reduced by omitting the photo process, and thus the manufacturing cost of the semiconductor package may be reduced.

While embodiments are described above, a person skilled in the art may understand that many modifications and variations are made without departing from the spirit and scope of the inventive concept defined in the following claims. Accordingly, the example embodiments of the inventive concept should be considered in all respects as illustrative and not restrictive, with the spirit and scope of the inventive concept being indicated by the appended claims.

What is claimed is:

1. A semiconductor package comprising:
a first semiconductor package; and
a second semiconductor package disposed on the first semiconductor package,
wherein the first semiconductor package comprises:
a lower redistribution substrate;
a connection substrate disposed on the lower redistribution substrate, wherein the connection substrate comprises a through hole, a first insulating layer and a through via penetrating the first insulating layer;
a lower semiconductor chip disposed in the through hole;
a connection layer disposed between the connection substrate and the lower redistribution substrate, wherein the connection layer comprises a first metal pattern and a solder pattern disposed on the first metal pattern;
a first molding layer disposed on the lower semiconductor chip and the connection substrate; and
an upper redistribution substrate disposed on the first molding layer,
wherein the second semiconductor package comprises:
a package substrate;
an upper semiconductor chip disposed on the package substrate; and
a second molding layer disposed on the package substrate and the upper semiconductor chip.

2. The semiconductor package of claim 1, wherein the first metal pattern, the solder pattern, and the through via vertically overlap each other, and
wherein the first insulating layer and the first molding layer comprise different materials from each other.

3. The semiconductor package of claim 1, wherein the first metal pattern includes nickel (Ni), and
wherein the solder pattern includes tin (Sn) and/or a tin-silver alloy (Sn—Ag).

4. The semiconductor package of claim 1, wherein the first insulating layer includes polypropylene glycol (PPG).

5. The semiconductor package of claim 1, wherein the lower redistribution substrate further comprises:
a plurality of lower redistribution patterns; and
a second insulating layer disposed between uppermost ones of the plurality of the lower redistribution patterns adjacent to each other in a first direction,
wherein the first metal pattern is disposed between the lower redistribution pattern and the first molding layer.

6. The semiconductor package of claim 5, wherein the second insulating layer includes Ajinomoto build-up film (ABF).

7. The semiconductor package of claim 1, wherein the first insulating layer overlaps a side surface of the solder pattern.

8. The semiconductor package of claim 1, wherein the connection layer further includes a second metal pattern,
wherein the second metal pattern is disposed between the first metal pattern and the solder pattern, and
wherein the second metal pattern comprises gold (Au).

9. The semiconductor package of claim 1, wherein a width of the through via measured in a first direction decreases and increases from an upper surface of the first insulating layer to a lower surface of the first insulating layer,
wherein the through via has an hourglass shape in a cross-sectional view.

10. The semiconductor package of claim 1, wherein a level of an upper surface of the through via is higher than a level of an upper surface of the first insulating layer, and
wherein an upper surface of the first molding layer and the upper surface of the through via are coplanar with each other.

11. The semiconductor package of claim 10, wherein the upper redistribution substrate comprises an upper redistribution pattern,
wherein the first molding layer overlaps at least a portion of a side surface of an upper portion of the through via, and
wherein the upper surface of the through via is in contact with the upper redistribution pattern.

12. The semiconductor package of claim 1, wherein the lower semiconductor chip comprises a lower chip body, a lower chip pad disposed on a lower surface of the lower chip body, and a connection terminal disposed on the lower chip pad,
wherein the first molding layer is in contact with a side surface of the connection terminal, and
wherein the first molding layer is spaced apart from the solder pattern.

13. The semiconductor package of claim 1, wherein the lower redistribution substrate comprises a lower redistribution pattern, and
wherein the solder pattern, the first metal pattern, and the lower redistribution pattern comprise materials different from each other.

14. A semiconductor package comprising:
a lower redistribution substrate;
a connection substrate disposed on the lower redistribution substrate, wherein the connection substrate comprises a through hole, a first insulating layer, and a through via penetrating the first insulating layer;
a lower semiconductor chip disposed in the through hole, wherein the lower semiconductor chip comprises a lower chip body, a lower chip pad disposed on a lower surface of the lower chip body, and a connection terminal disposed under the lower chip pad;
a connection layer disposed between the connection substrate and the lower redistribution substrate, wherein the connection layer comprises a first metal pattern, a second metal pattern disposed on the first metal pattern, and a solder pattern disposed on the second metal pattern;
a molding layer overlapping the lower semiconductor chip and the connection substrate; and
an upper redistribution substrate disposed on the molding layer,
wherein a lower surface of the through via is in contact with an upper surface of the solder pattern,
wherein the through via has a first width measured in a first direction at a level of an upper surface of the first insulating layer and a second width measured in the first direction at a level of a lower surface of the first insulating layer,
wherein the through via has a third width measured at a point inside the first insulating layer, and
wherein the third width is smaller than the first width and the second width and
wherein the solder pattern and the connection terminal comprise the same material.

15. The semiconductor package of claim 14, wherein the lower redistribution substrate further comprises:
a plurality of lower redistribution patterns; and
a second insulating layer disposed between uppermost ones of the plurality of the lower redistribution patterns adjacent to each other in the first direction,
wherein the first metal pattern, the second metal pattern, and the solder pattern are spaced apart from the second insulating layer.

16. The semiconductor package of claim 15, wherein a lower surface of the through via and a lower surface of the first insulating layer are coplanar with each other.

17. The semiconductor package of claim 15, wherein the first metal pattern, the second metal pattern, and the solder pattern comprise materials different from each other, and
wherein side surfaces of the first metal pattern, side surfaces of the second metal pattern, and side surfaces of the solder pattern are in contact with the molding layer.

18. The semiconductor package of claim 14, wherein the lower semiconductor chip comprises a lower chip body and a lower chip pad disposed on a lower surface of the lower chip body, and
wherein a level of a lower surface of the first insulating layer is lower than a level of a lower surface of the lower chip pad.

19. The semiconductor package of claim 14, wherein a width of the solder pattern measured in the first direction is greater than a width of the first metal pattern measured in the first direction.

20. A semiconductor package comprising:
a lower redistribution substrate;
a lower semiconductor chip disposed on the lower redistribution substrate;
a connection substrate surrounding the lower semiconductor chip, wherein the connection substrate comprises an insulating layer having a through hole and a through via penetrating the insulating layer;
a connection layer disposed between the connection substrate and the lower redistribution substrate; and
a molding layer disposed on the lower semiconductor chip, the connection substrate, and the connection layer,
wherein the connection layer comprises metal patterns and a solder pattern disposed on the metal patterns which are sequentially stacked in a region vertically overlapping the through via of the connection substrate,
wherein the metal patterns, the solder pattern, and the through via vertically overlap each other,
wherein the metal patterns, the solder pattern, and the through via comprise materials different from each other, and
wherein the through via has a shape of an hourglass in a cross-sectional view.

21. The semiconductor package of claim 20, wherein the lower semiconductor chip comprises a lower chip body and a lower chip pad disposed on a lower surface of the lower chip body, and
wherein a level of a lower surface of the insulating layer is lower than a level of a lower surface of the lower chip pad.
